(19) United States
(12) Patent Application Publication
(10) Pub. No.: US 2026/0247675 A1
(43) Pub. Date: Aug. 20, 2026

(54) METHOD FOR HETEROEPITAXIAL DEPOSITION OF DIAMOND AND WAFER PRODUCED THEREBY

(71) Applicant: Fraunhofer-Gesellschaft zur Förderung der angewandten Forschung e.V., Munich (DE)

(72) Inventors: Jan KUSTERMANN, Freiburg (DE); Jan ENGELS, Freiburg (DE)

(73) Assignee: Fraunhofer-Gesellschaft zur Förderung der angewandten Forschung e.V., Munich (DE)

(21) Appl. No.: 19/534,546

(22) Filed: Feb. 9, 2026

(30) Foreign Application Priority Data
Feb. 20, 2025 (DE) 10 2025 106 576.4

(51) Int. Cl. H10D 62/83; C30B 25/10

(52) U.S. Cl. CPC H10D 62/8303; C30B 25/105

(57) ABSTRACT

Methods are provided for the heteroepitaxial deposition of diamond on a substrate by chemical vapor deposition (CVD), comprising the following steps: generating a nucleation layer on the substrate; overgrowing the nucleation layer with a diamond layer by chemical vapor deposition; partial removal of the diamond layer by dry chemical etching, wherein the dry chemical etching is carried out by the action of a plasma which comprises hydrogen and oxygen; overgrowing the diamond layer by chemical vapor deposition; and cyclic repetition of the partial removal of the diamond layer and the overgrowing of the diamond layer. Furthermore, wafers manufactured in this manner are provided.

### CROSS-REFERENCE TO RELATED APPLICATIONS

This application claims priority under 35 USC § 119 to German Patent Application No. 10 2025 106 576.4 filed Feb. 20, 2025, which is hereby incorporated herein by reference.

### BACKGROUND OF THE INVENTION

The invention relates to a method for the heteroepitaxial deposition of diamond on a substrate using chemical vapor deposition, comprising the following steps: depositing a nucleation layer on at least a part of the substrate and growing a diamond layer by chemical vapor deposition on the nucleation layer. Furthermore, the invention relates to a wafer with a diameter of 5 cm or more and a thickness of 200 μm or more, which comprises or consists of diamond.

Known methods for depositing diamond use chemical vapor deposition. Such a method includes the generation of a plasma from a working gas. Said working gas may comprise at least hydrogen and a hydrocarbon. The substrate on which diamond is to be deposited may be heated to a temperature above 650° C. Such methods can be used to deposit single-crystalline, polycrystalline, or amorphous carbon layers, which may consist at least partly of sp³-hybridized carbon. The deposited diamond layer may experience high mechanical stress during heteroepitaxy on foreign substrates, which is a known disadvantage of these methods. The mechanical stress may lead to cracking in the diamond layer or to the diamond layer detaching from the substrate if a critical thickness is exceeded.

To reduce mechanical stress in the diamond layer, DE 10 2022 205 081 A1 discloses pre-curving the substrate at room temperature in such a way that the deformations occurring during the diamond growth at high temperature result in a substantially flat substrate surface. Diamond layers can thus be grown on a flat substrate surface, enabling the production of flat single-crystal diamond layers over large areas. However, manufacturing pre-curved substrates is prone to errors and time-consuming.

### BRIEF DESCRIPTION OF THE DRAWINGS

The accompanying figures, where like reference numerals refer to identical or functionally similar elements throughout the separate views, which are not true to scale, and which, together with the detailed description below, are incorporated in and form part of the specification, serve to illustrate further various embodiments and to explain various principles and advantages all in accordance with the devices, apparatuses, and methods. Advantages of embodiments of the systems, apparatuses, and methods will be apparent from the following detailed description of the exemplary embodiments thereof, which description should be considered in conjunction with the accompanying drawings in which:

FIG. 1 illustrates the gas phase deposition of diamond by chemical vapor deposition (CVD);

FIG. 2 illustrates a flow chart of a method according to the invention;

FIG. 3 illustrates a cross-sectional view of a wafer produced by a method according to the invention;

FIG. 4 illustrates photoluminescence spectra of a wafer produced by a method according to the invention;

FIG. 5 illustrates an X-ray structural analysis of a wafer produced by a method according to the invention; and

FIG. 6 shows the results of a phase diffractogram.

### DETAILED DESCRIPTION

As required, detailed embodiments of the devices, products, apparatuses, and methods are disclosed herein; however, it is to be understood that the disclosed embodiments are merely exemplary of the devices, products, apparatuses, and methods which can be embodied in various forms. Therefore, specific structural and functional details disclosed herein are not to be interpreted as limiting, but merely as a basis for the claims and as a representative basis for teaching one skilled in the art to variously employ the devices, products, apparatuses, and methods in virtually any appropriately detailed structure. Further, the terms and phrases used herein are not intended to be limiting; but rather, to provide an understandable description of the devices, products, apparatuses, and methods. While the specification concludes with claims defining the features of the devices, products, apparatuses, and methods that are regarded as novel, it is believed that the devices, products, apparatuses, and methods will be better understood from a consideration of the following description in conjunction with the drawing figures, in which like reference numerals are carried forward.

In the following detailed description, reference is made to the accompanying drawings which form a part hereof, and in which are shown by way of illustration embodiments that may be practiced. It is to be understood that other embodiments may be utilized and structural or logical changes may be made without departing from the scope. Therefore, the following detailed description is not to be taken in a limiting sense.

Alternate embodiments may be devised without departing from the spirit or the scope of the invention. Additionally, well-known elements of exemplary embodiments of the devices, products, apparatuses, and methods will not be described in detail or will be omitted so as not to obscure the relevant details of the systems, apparatuses, and methods.

Before the devices, products, apparatuses, and methods are disclosed and described, it is to be understood that the terminology used herein is for the purpose of describing particular embodiments only and is not intended to be limiting. The terms “comprises,” “comprising,” or any other variation thereof are intended to cover a non-exclusive inclusion, such that a method, method, article, or apparatus that comprises a list of elements does not include only those elements but may include other elements not expressly listed or inherent to such method, method, article, or apparatus. An element proceeded by “comprises a” does not, without more constraints, preclude the existence of additional identical elements in the method, method, article, or apparatus that comprises the element. The terms “including” and/or “having,” as used herein, are defined as comprising (i.e., open language). The terms “a” or “an”, as used herein, are defined as one or more than one. The term “plurality,” as used herein, is defined as two or more than two. The term “another,” as used herein, is defined as at least a second or more. The description may use the terms “embodiment” or “embodiments,” which may each refer to one or more of the same or different embodiments.

For the purposes of the description, a phrase in the form “A/B” or in the form “A and/or B” or in the form “at least one of A and B” means (A), (B), or (A and B), where A and B are variables indicating a particular object or attribute. When used, this phrase is intended to and is hereby defined as a choice of A or B or both A and B, which is similar to the phrase “and/or”. Where more than two variables are present in such a phrase, this phrase is hereby defined as including only one of the variables, any one of the variables, any combination of any of the variables, and all of the variables, for example, a phrase in the form “at least one of A, B, and C” means (A), (B), (C), (A and B), (A and C), (B and C), or (A, B and C).

Relational terms such as first and second, top and bottom, and the like may be used solely to distinguish one entity or action from another entity or action without necessarily requiring or implying any actual such relationship or order between such entities or actions. The description may use perspective-based descriptions such as up/down, back/front, top/bottom, and proximal/distal. Such descriptions are merely used to facilitate the discussion and are not intended to restrict the application of disclosed embodiments. Various operations may be described as multiple discrete operations in turn, in a manner that may be helpful in understanding embodiments; however, the order of description should not be construed to imply that these operations are order dependent.

As used herein, the term “about” or “approximately” applies to all numeric values, whether or not explicitly indicated. These terms generally refer to a range of numbers that one of skill in the art would consider equivalent to the recited values (i.e., having the same function or result). In many instances these terms may include numbers that are rounded to the nearest significant figure. As used herein, the terms “substantial” and “substantially” means, when comparing various parts to one another, that the parts being compared are equal to or are so close enough in dimension that one skill in the art would consider the same. Substantial and substantially, as used herein, are not limited to a single dimension and specifically include a range of values for those parts being compared. The range of values, both above and below (e.g., “+/−” or greater/lesser or larger/smaller), includes a variance that one skilled in the art would know to be a reasonable tolerance for the parts mentioned.

Herein various embodiments of the systems, apparatuses, and methods are described. In many of the different embodiments, features are similar. Therefore, to avoid redundancy, repetitive description of these similar features may not be made in some circumstances. It shall be understood, however, that description of a first-appearing feature applies to the later described similar feature and each respective description, therefore, is to be incorporated therein without such repetition.

According to one aspect, a method for the heteroepitaxial deposition of diamond is described. Within the scope of this disclosure, heteroepitaxial deposition means that at least one layer which substantially comprises or consists of diamond is deposited on a substrate which consists of a material different from diamond. The substrate can be polygonal or round in shape. The substrate may have a first side and an opposing second side which are connected and delimited by at least one side surface. Thus, the first and second sides may constitute the largest surfaces of said substrate. The surface of the substrate can be substantially flat. Within the scope of this disclosure, a flat substrate surface is a surface that has a radius of curvature or radii of curvature of more than about 5 m. In some embodiments of the invention, the radius of curvature may be more than about 10 m or more than about 20 m or more than about 100 m.

The substrate may be made from monocrystalline or polycrystalline or amorphous material. In some embodiments of the invention, the substrate may comprise or consist of a homogeneous material. In other embodiments of the invention, the substrate itself may be coated or composed of multiple layers made from the same or different material compositions.

In some embodiments of the invention, the substrate may be a silicon wafer. In some embodiments of the invention, the substrate may comprise a silicon wafer. In other embodiments of the invention, the substrate may comprise any of strontium titanate, aluminum nitride, and zirconium oxide. In some embodiments, ceramic substrates may also comprise yttrium. Furthermore, the substrate may comprise or consist of iridium. In some embodiments of the invention, the substrate may comprise a silicon wafer coated with yttrium-stabilized zirconium oxide and/or aluminum nitride. An optional coating comprising Iridium may be applied to the yttrium-stabilized zirconium oxide and/or aluminum nitride layer. The silicon wafer may have a thickness of about 0.5 mm to about 5 mm, or about 2 mm to about 5 mm, or about 0.5 mm to about 3 mm, or about 2 mm to about 3 mm. The layers of yttrium-stabilized zirconium oxide and iridium may have a thickness of approximately 80 nm to approximately 200 nm, or approximately 80 nm to approximately 150 nm, or approximately 110 nm to approximately 130 nm.

In some embodiments of the invention, the substrate may be placed in a vacuum chamber and heated to an elevated temperature. In one embodiment of the invention, the temperature may be selected from approximately 650° C. to approximately 1200° C. In another embodiment of the invention, the temperature may be selected from approximately 750° C. to approximately 950° C. In still another embodiment of the invention, the temperature may be selected from approximately 800° C. to approximately 900° C. In still another embodiment of the invention, the temperature may be selected from approximately 840° C. to approximately 860° C.

The substrate can be given a specific electrical potential using an electrical voltage source. Furthermore, the vacuum chamber can be located within a microwave resonator, can itself be a microwave resonator, or can be equipped with an internal antenna through which microwave radiation can be coupled into the interior. Microwave radiation is used to ionise and activate a working gas introduced into the vacuum chamber. The resulting ions, electrons and/or photons are directed onto the substrate's surface to enable diamond deposition. The microwave radiation may have a frequency ranging from approximately 900 MHz to 950 MHz, or from 2.4 GHz to 2.5 GHZ.

In a first method step, a substrate is provided and a nucleation layer is deposited on at least a part of at least one surface of said substrate. In some embodiments, the nucleation layer can be produced by applying nanodiamonds or diamond dust or diamond granulate to the surface. In other embodiments of the invention, the nucleation layer can be produced from a plasma as described above or from an activated gas phase. Said plasma or gas phase may comprise at least hydrogen and a hydrocarbon such as methane to produce the nucleation layer. The hydrocarbon content can range from approximately 1% to approximately 5%. A first electrical bias voltage can be applied to the substrate during deposition of said nucleation layer. In some embodiments of the invention, said bias voltage may be a negative bias voltage with respect to ground potential. The deposition of the nucleation layer may take between about 0.1 h and about 3 h, or about 0.5 h to about 2 h, or about 0.75 h to about 1.5 h. Notwithstanding its designation as a layer, the nucleation layer does not have to cover the whole substrate surface. The nucleation layer may be a partial coating of the substrate or a cluster of islands or spots separated from each other on the surface of the substrate.

In a second method step, the nucleation layer may be overgrown with a first diamond layer. In some embodiments of the invention, a second electrical bias voltage can be applied to the substrate during deposition of said first diamond layer. In other embodiments of the invention, a self bias can be applied to the substrate during deposition of said first diamond layer. Self biasing means that the substrate is electrically insulated within the vacuum chamber, whereby, depending on the plasma conditions, an electrical potential is established on the substrate which may differ from the earth potential of the surrounding vacuum chamber. In some embodiments of the invention, the first diamond layer may be deposited from an activated gas phase or plasma comprising substantially hydrogen and a hydrocarbon. The hydrocarbon may comprise any of methane, ethane, and acetylene. The portion of hydrocarbon may be between about 1% and about 5%, or between about 1% and about 3.5%, or between about 1.25% and about 1.75%, or between about 3% and about 3.5%. The second method step may continue until the nucleation layer is completely overgrown with the first diamond layer or the first diamond layer covers the substrate surface such that no point defects or holes remain in the first diamond layer. This may last between about 1 hour and about 6 hours, or between about 3 hours and about 5 hours, or between about 3.5 hours and about 4.5 hours.

In a third method step, the first diamond layer deposited in the second step may be partially removed or thinned using dry chemical etching. In some embodiments, the dry chemical etching may be carried out by exposing the diamond layer to a plasma comprising hydrogen. In another embodiment, the dry chemical etching may be carried out by exposing the first diamond layer to a plasma comprising hydrogen and oxygen. In some embodiments, the oxygen content may be selected from about 0.3% to about 3%. In some embodiments, the oxygen content may be selected from about 1.5% to about 2.5%. In some embodiments, the oxygen content may be selected from about 1.8% to about 2.2%. In other embodiments, the oxygen content may be higher than about 0.3%, about 0.5%, about 0.8% or about 1.0%. In these embodiments, the oxygen content may be less than about 3%, about 2.5%, about 2.25% or about 2.1%. In some embodiments, the dry chemical etching process may take between two and five hours.

In a fourth method step, a second diamond layer is deposited by chemical vapor deposition on the remaining surface of the first diamond layer. The diamond growth during the fourth method step may be carried out using identical or similar parameters to those used in the second method step.

In a subsequent method step, the second diamond layer deposited in the fourth method step may be partially removed or thinned using dry chemical etching as detailed above with respect to the third method step. The growth of diamond layers according to the second and fourth method steps and the partial removal of these diamond layers by dry chemical etching according to the third method step may be repeated cyclically. As the diamond layer grown is only partially removed or thinned, the total layer thickness of the cyclically grown and removed diamond layers increases continuously.

In some embodiments, the above-detailed method steps may be repeated cyclically until the total thickness of all diamond layers exceeds approximately 200 μm. In another embodiment, the above-detailed method steps may be repeated cyclically until the total thickness of all diamond layers exceeds approximately 300 μm. In still another embodiment, the above-detailed method steps may be repeated cyclically until the total thickness of all diamond layers exceeds approximately approximately 400 μm. In some embodiments, repeatedly growing and partially removing diamond layers can reduce the mechanical stress within them. This enables large overall thicknesses to be deposited on large-area substrates without cracking or detachment or the wafer experiencing bending.

In some embodiments of the invention, the partial removal of the diamond layer followed by the deposition of a further diamond layer may be repeated between about 10 and about 80 times. In other embodiments of the invention, the partial removal of the diamond layer followed by the deposition of a further diamond layer may be repeated between about 20 times and about 60 times. In still other embodiments of the invention, the partial removal of the diamond layer followed by the deposition of a further diamond layer may be repeated between about 30 times and about 60 times. In some embodiments of the invention, this may result in a total thickness of the diamond of more than 200 μm or more than 300 μm or more than 400 μm. In some embodiments of the invention, the diamond may have an overall thickness of less than about 500 μm or less than about 1 mm or less than about 2 mm. The diamond may be sufficiently thick to form a stable wafer, even when free-standing without an adhering substrate. For example, it could be used as a window for electromagnetic radiation.

In some embodiments of the invention, the substrate may have a diameter of more than 5 cm or 2 inches. In other embodiments of the invention, the substrate may have a diameter of more than 7.5 cm or 3 inches. In still other embodiments of the invention, the substrate may have a diameter of more than 10 cm or 4 inches. In some embodiments of the invention, the diameter off the substrate may be less than about 31 cm or 12 inches. In other embodiments of the invention, the diameter may be less than about 26 cm or 10 inches. In still other embodiments of the invention, the substrate may have a diameter of less than about 10 cm or 4 inches. Substrates of this size can be used for a variety of purposes, including as windows for electromagnetic radiation, heat spreaders and substrates for electronic components.

In some embodiments of the invention, executing the second and/or fourth method step once may deposit a diamond layer with a thickness of between 0.5 μm and 1 μm. In other embodiments of the invention, executing the second and/or fourth method step once may deposit a diamond layer with a thickness of between 4 μm to 30 μm. In still other embodiments of the invention, executing the second and/or fourth method step once may deposit a diamond layer with a thickness of between 1 μm to about 4 μm. In still other embodiments of the invention, executing the second and/or fourth method step once may deposit a diamond layer with a thickness of between 16 μm to about 20 μm. In still other embodiments of the invention, executing the second and/or fourth method step once may deposit a diamond layer with a thickness of between 4 μm to about 15 μm. This enables good control of the mechanical stresses that occur, as well as rapid growth to the desired final thickness in a small number of cycles.

In some embodiments of the invention, the first four to eight diamond layers may have a lower thickness than subsequent layers. This reduces initial lattice mismatches at the interface with the substrate surface and/or increases crystalline quality at this interface.

In some embodiments of the invention, the diamond layers deposited in the fourth method step may have a orientation. In other embodiments of the invention, the diamond layers deposited in the fourth method step may have a orientation. The crystal orientation of the diamond layer surface is specified as a Miller index. In some embodiments of the invention, partially removing the diamond layer by dry chemical etching in the third method step may lead to pyramids forming on the surface. In some embodiments, these pyramids may have at least one side with a orientation. These pyramids may have a height ranging from about 2 μm to 5 μm, measured in the normal direction of the substrate surface. The structuring of the diamond layers caused by dry chemical etching may contribute to reducing mechanical stresses and thus improving the crystal quality of the diamond layers deposited according to the invention.

In some embodiments of the invention, the last diamond layer may be deposited nominally undoped, whereas the underlying layers are at least partially doped with a dopant. The dopant may be selected from any of nitrogen, phosphorus, and/or boron. In some embodiments, doping allows layers or areas within the diamond to be deposited which have a predeterminable conductivity. In other embodiments, doping allows layers or areas within the diamond to be deposited which include color centers. In some embodiments of the invention, the color centers may include nitrogen vacancy centers.

In some embodiments of the invention, the substrate may be removed after the last diamond layer has been deposited. The substrate can be removed using wet or dry chemical etching, or through mechanical machining. Another layer of diamond can be deposited on a wafer produced in this way using gas-phase homoepitaxy to increase its thickness further. Due to homoepitaxial deposition, mechanical stresses occur to a lesser extent or are completely eliminated, enabling a greater layer thickness to be achieved with conventional growth and without intermittent etching steps.

In some embodiments of the invention, the diamond produced by the described method may be monocrystalline. Monocrystalline diamond layers may have a higher crystal quality and a lower absorption coefficient than polycrystalline diamond layers. The absorption coefficient may range from approximately 0.25 cm⁻¹ to 0.35 cm⁻¹ for wavelengths between 680 and 780 nm.

The method described allows for the reliable control of mechanical stresses, resulting in a wafer with low curvature and shape tolerances. In some embodiments of the invention, the maximum deviation of the wafer's median surface from a reference plane may be less than 100 μm or 50 μm.

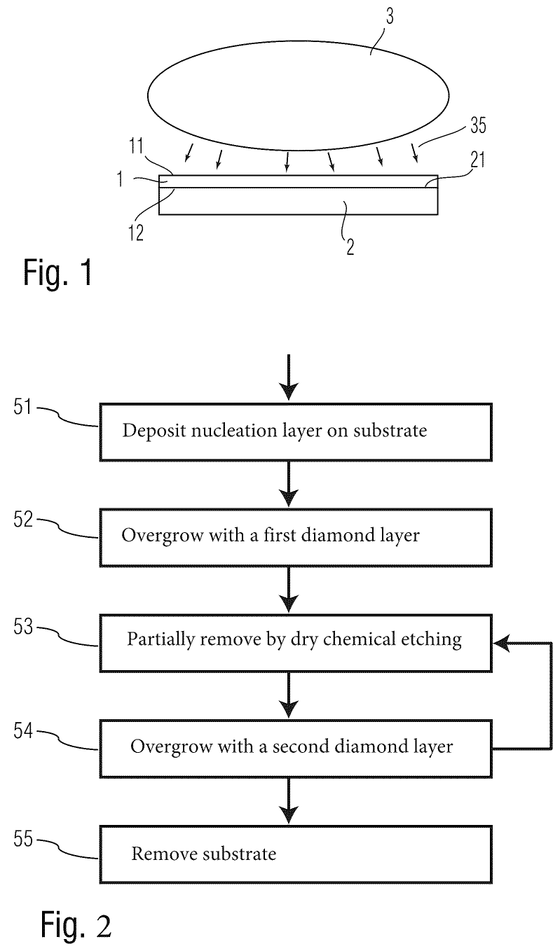

Turning now to the drawings, in which like reference numerals indicate like elements, FIG. 1 illustrates the production of a crystalline diamond wafer by chemical vapor deposition. FIG. 1 shows a cross-section of a substrate 2 with a first side 21. Opposite first side 21 is plasma 3. The plasma is generated by exposing a working gas to microwave radiation, which at least partially ionizes the gas. The working gas and substrate 2 are located in a vacuum chamber that is part of a microwave resonator for this purpose.

Depending on the composition of the working gas in plasma 3, either diamond can be deposited from the plasma or a diamond layer 1 on substrate 2 can be dry-chemically etched. To accomplish this, ions, neutral particles, electrons, and/or photons act on the first side of the substrate. The energy of the incident charged particles can be altered by applying an electrical potential with a voltage source (not shown).

The plasma 3 interacts with the substrate 2, leading to the deposition of diamond 1, which has a first side 11 and an opposite second side 12. The second side 12 is in contact with the first side 21 of the substrate. Depending on the composition of the working gas, the first side 11 either overgrows or is partially removed by dry chemical etching. uring growth and/or etching, the substrate 2 can be heated by a heating device (not shown). The temperature can be set to any value between 800° and 900°, 840° and 860°, or 650° and 1200°.

The working gas 3 may have a pressure from about 50 mbar to about 200 mbar. In other embodiments of the invention, the pressure may be between about 70 mbar and about 90 mbar. In still other embodiments of the invention, the pressure may be between about 110 mbar and about 130 mbar.

The working gas of plasma 3 substantially comprises hydrogen during deposition of a diamond layer to which 1-5% methane is added. Other hydrocarbons, such as ethane or acetylene, may also be used in other embodiments of the invention. Additionally, dopants such as nitrogen, phosphorus, or boron may be added to the working gas. These dopants may be present in concentrations ranging from 1000 ppm to 4000 ppm. Additionally, the working gas may contain unavoidable impurities, such as other hydrocarbons or argon. Some embodiments of the invention include adding approximately 0.1% to 1% or 0.2% to 0.4% oxygen to the working gas.

For dry chemical etching of the first side 11 of the diamond layer 1, a working gas consisting substantially of hydrogen and containing approximately 1.5% to 2.5% oxygen may be used. Additionally, the working gas may contain unavoidable impurities such as hydrocarbons, argon, or nitrogen. Cyclically changing the composition of the working gas, and adjusting the microwave power and/or the substrate temperature if necessary, allows for switching between chemical vapor deposition of a diamond layer and its partial removal or thinning by dry chemical etching. A control or regulation device that implements the method disclosed may be provided for this purpose.

FIG. 2 shows a flowchart that explains the disclosed method in more detail. In the first method step 51, a substrate 2 is provided, which, for example, comprises or consists of a monocrystalline silicon wafer. The silicon wafer may be coated with an optional ceramic layer. In some embodiments of the invention, the ceramic layer may comprise or consist of yttrium-stabilized zirconia and/or aluminum nitride. Metallic iridium may be optionally deposited on this ceramic layer. The silicon wafer may have a thickness of about 2 mm to about 3 mm or from about 1 mm to about 5 mm. The layers deposited thereon may have a total layer thickness of about 80 nm to about 200 nm or from about 110 nm to about 130 nm.

In the first method step 51, a nucleation layer is deposited on the substrate. This layer can be formed by adding 1-5% methane to the plasma-forming working gas while applying a negative electrical bias to the substrate. This creates nucleation seeds, which enable the deposition of a crystalline diamond layer in the second method step.

In the second method step 52, said nucleation layer is overgrown with a first diamond layer. This layer is deposited by chemical vapor deposition, as described above in connection with FIG. 1. This layer may have a thickness ranging from approximately 0.5 μm to 1 μm. In some embodiments of the invention, the first diamond layer can cover the first side 21 of the substrate 2 completely or nearly completely without exhibiting impermissibly high mechanical stresses.

In the subsequent third method step 53, the first diamond layer is partially removed by dry chemical etching. This process may reduce the thickness of the diamond layer deposited in the second step. In other embodiments of the invention, pyramids or pyramid-like structures may form on the diamond layer. These structures may have side surfaces that are at least partially oriented [111].

In the subsequent fourth method step 54, the first diamond layer etched in the previous method step 53 is overgrown homoepitaxially with a second diamond layer by chemical vapor deposition. This second diamond layer may have a layer thickness of about 4 μm to about 30 μm, or about 16 μm to about 20 μm, or about 4 μm to about 15 μm. The first side 11 facing the plasma 3 may have a orientation or a orientation.

After that, method steps 53 and 54 are repeated cyclically. In other words, each deposited diamond layer is partially removed or thinned by dry chemical etching before being overgrown by another diamond layer. The first four to eight diamond layers may have a reduced thickness compared to the subsequent layers. Method steps 53 and 54 may be repeated a total of approximately 10 to 80 times, or more frequently, until diamond 1 has the desired overall thickness. In some embodiments of the invention, the desired overall thickness may exceed 200 μm, 250 μm, or 300 μm.

In the final method step 55, the substrate 2 may be removed by wet or dry chemical etching and/or mechanical methods such as milling, leaving the diamond 1 as a free-standing monocrystalline diamond wafer. The diamond wafer can then undergo further processing, such as the deposition of additional diamond layers until the desired final thickness is achieved, which can be several millimeters.

### First Example of Implementation

Yttrium-stabilized zirconium oxide with a layer thickness of 90 nm was deposited on silicon wafers 2 mm or 3 mm thick. A layer of 30 nm metallic iridium was then applied. The working gas was ionized at a pressure of 120 mbar using 915 MHz microwave radiation.

The diamond layers were etched in the third method step 53 using the following parameters:

| Parameter | Value |
|---|---|
| Substrate temperature | 820° C.-840° C. |
| Oxygen content in the working gas | 2.0% |
| Etching time per cycle (53) | 4 hours |
| | (first 6 cycles: 2 h) |

The growth of the diamond layers in the fourth method step 54 was carried out using the following parameters:

| Parameter | Value |
|---|---|
| Substrate temperature | 840° C.-860° C. |
| Methane content in the working gas | 1.25 |
| Growth time per cycle (54) | 5 hours |
| | (first 6 cycles: 4 hours) |
| Nitrogen content in working gas | 3040 ppm |
| Oxygen content in working gas | 0.15% |

After 38 cycles totaling 385 hours, a diamond with an overall thickness of 300 μm was deposited. The diamond could be removed from the substrate without sustaining damage. The wafer produced in this way had a curvature of more than 10 m, and X-ray diffraction analysis confirmed that the diamond was single-crystalline.

### Second Example of Implementation

Yttrium-stabilized zirconium oxide with a layer thickness of 90 nm was deposited on 2 mm or 3 mm thick silicon wafers. A layer of 30 nm metallic iridium was then applied. The working gas was ionized at a pressure of 120 mbar using 915 MHz microwave radiation.

The diamond layers were etched in the third method step 53 using the following parameters:

| Parameter | Value |
|---|---|
| Substrate temperature | 820° C.-840° C. |
| Oxygen content in the working gas | 2.0% |
| Etching time per cycle (53) | 4 hours |
| | (first 6 cycles: 2 h) |

The growth of the diamond layers in the fourth method step 54 was carried out using the following parameters:

| Parameter | Value |
|---|---|
| Substrate temperature | 840° C.-860° C. |
| Methane content in the working gas | 1.75% |
| Growth time per cycle (54) | 4 hours |
| | (first 6 cycles: 2.5 hours) |
| Nitrogen content in working gas | 3040 ppm |
| Oxygen content in working gas | 0.15% |

After 30 cycles totaling 215 hours, a layer of diamond with an overall thickness of 500 μm was deposited. It could then be removed from the substrate without sustaining any damage. The wafer produced in this way had a curvature of more than 10 m, and X-ray diffraction analysis confirmed that the diamond was monocrystalline.

### Third Example of Implementation

The substrate corresponded to that of the first and second examples. The working gas was ionized at a pressure of 80 mbar using 2.45 GHz microwave radiation.

The diamond layers were etched in the third method step 53 using the following parameters:

| Parameter | Value |
|---|---|
| Substrate temperature | 680° C.-720° C. |
| Oxygen content in the working gas | 2.0% |
| Etching time per cycle (53) | 0.5 hours |

The growth of the diamond layers in the fourth method step 54 was carried out using the following parameters:

| Parameter | Value |
|---|---|
| Substrate temperature | 760° C.-800° C. |
| Methane content in the working gas | 3.3% |
| Growth time per cycle (54) | 4 hours |
| | (first cycle: 10 h) |
| Nitrogen content in working gas | 90 ppm |
| Oxygen content in working gas | 0.4% |

After 14 cycles totaling 66 hours, a layer of diamond with an overall thickness of 250 μm was deposited. It could then be removed from the substrate without sustaining any damage. The wafer produced in this way had a curvature of more than 10 m, and X-ray diffraction analysis confirmed that the diamond was single-crystalline.

The optical transparency of the manufactured diamond wafers was analyzed using UV/VIS measurements of the absorption coefficient from 680 nm to 760 nm, which resultedina value of less than 0.3 cm⁻¹.

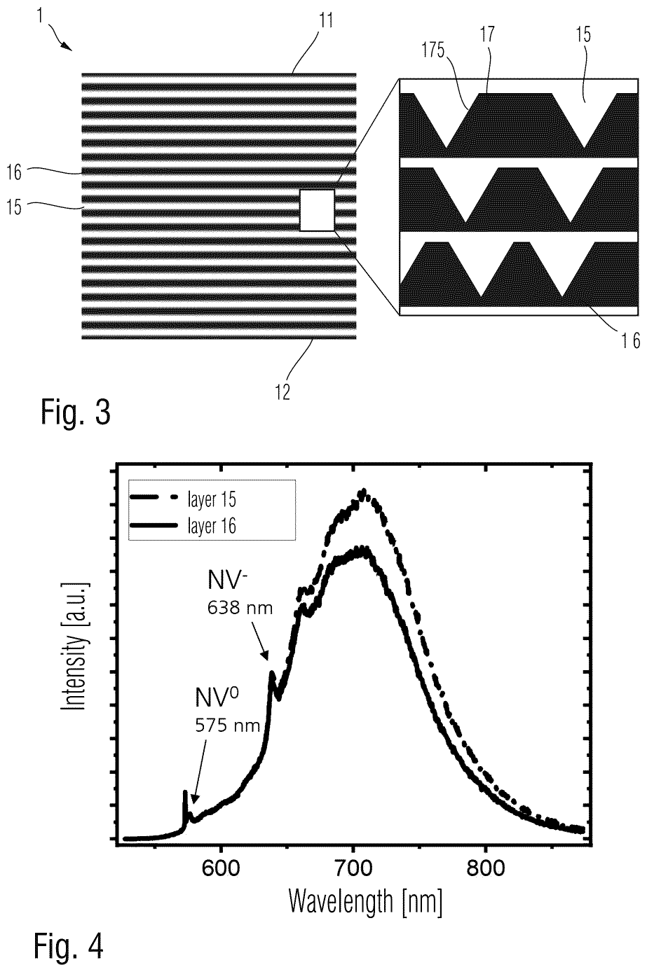

FIG. 3 shows a cross-section through a diamond wafer 1 manufactured according to the invention. In FIG. 3, the first side 11 of the diamond is shown at the top. The opposite second side 12 of the diamond, which was in contact with the substrate 2 during growth, is shown at the bottom of FIG. 3. As FIG. 3 shows, the diamond 1 is composed of a plurality of layers 15 and 16, which are arranged cyclically within the diamond 1 due to the cyclic sequence of method steps 53 and 54.

FIG. 3 shows an enlarged view of three layers. This enlargement reveals that dry chemical etching creates pyramids 17 within a diamond layer. These pyramids have at least some side surfaces 175 with a orientation. In some embodiments of the invention, the first side of the further diamond layer 15 deposited on the pyramids 17 may have a orientation. This may accelerate growth and/or improve the incorporation of dopants. The proposed layer structure effectively eliminates mechanical stresses within the diamond, enabling it to be provided as a free-standing wafer with a large surface area. For example, it can have a diameter of more than 5 cm (2 in), 7.5 cm (3 in), or 10 cm (4 in).

FIG. 4 shows photoluminescence measurements on the wafer depicted schematically in FIG. 3. The ordinate shows the intensity of the luminescence light against the wavelength in nanometers on the abscissa. FIG. 4 displays the zero-phonon line of the neutral and negatively charged nitrogen vacancy center, along with the associated phonon sidebands for diamond layers 15 and 16, which were thinned by etching in method step 53 and deposited in method step 54. As FIG. 4 shows, the intensities of the two layers in the photoluminescence spectrum differ only at wavelengths above 635 nm; below 635 nm, they remain constant. Therefore, the described method can be used to produce high-quality crystalline diamonds.

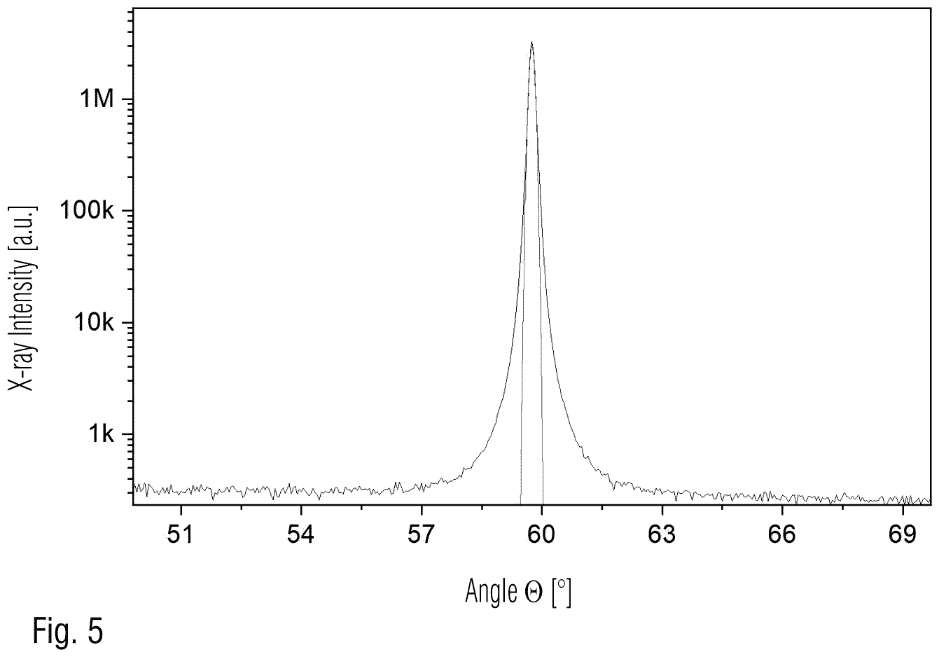

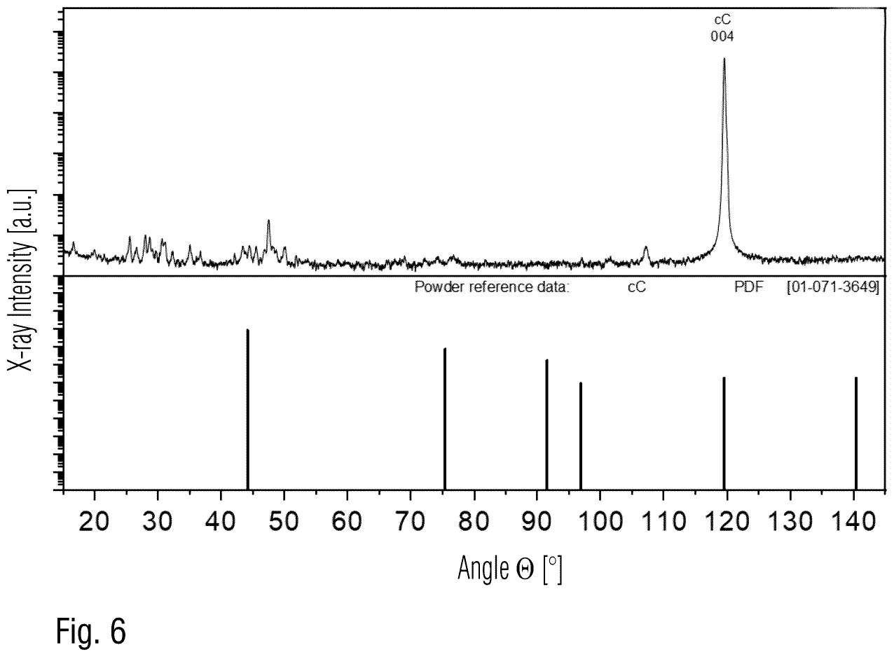

FIGS. 5 and 6 show the results of an X-ray diffraction analysis of a 255 μm thick diamond layer produced using the disclosed method according to the third embodiment. FIG. 5 shows a smay angle (rocking curve), with the angle of incidence on the x-axis and the measured X-ray intensity on the y-axis. FIG. 6 shows the results of a phase diffractogram.

The measurement data in FIG. 5 demonstrate a Gaussian distribution of X-ray intensity versus angle, with a full width at half maximum (FWHM) of 0.13°. These results demonstrate the high quality of the single-crystal diamond layers produced according to the invention.

FIG. 6 shows the results of a phase diffractogram from an X-ray diffraction (XRD) analysis of a 255-μm-thick diamond layer produced using the proposed method according to the third embodiment. The figure shows an angle smay, with the angle of incidence on the x-axis and the measured X-ray intensity on the y-axis.

The measurement data in FIG. 6 show an intensity peak at approximately 119.5°. This is the cC004 peak associated with diamond grown in the orientation. In contrast, a polycrystalline diamond film would show further peaks at 43.9° ([111]), 75.3° ([220]), 91.5° ([311]) and 140.6° ([331]).

Of course, the invention is not limited to the illustrated embodiments. Therefore, the above description should not be considered limiting but explanatory. The below claims should be understood in such a way that a described feature is available in at least one exemplary embodiment. This does not rule out the presence of further features. If the claims and the above description define “first” and “second” embodiments, this designation serves to distinguish between two similar embodiments without determining an order.

It is noted that various individual features of the inventive methods and systems may be described only in one exemplary embodiment herein. The particular choice for description herein with regard to a single exemplary embodiment is not to be taken as a limitation that the particular feature is only applicable to the embodiment in which it is described. All features described herein are equally applicable to, additive, or interchangeable with any or all of the other exemplary embodiments described herein and in any combination or grouping or arrangement. In particular, use of a single reference numeral herein to illustrate, define, or describe a particular feature does not mean that the feature may not be associated or equated to another feature in another drawing figure or description. Further, where two or more reference numerals are used in the figures or in the drawings, this should not be construed as being limited to only those embodiments or features, they are equally applicable to similar features or not a reference numeral is used or another reference numeral is omitted.

The foregoing description and accompanying drawings illustrate the principles, exemplary embodiments, and modes of operation of the systems, apparatuses, and methods. However, the systems, apparatuses, and methods should not be construed as being limited to the particular embodiments discussed above. Additional variations of the embodiments discussed above will be appreciated by those skilled in the art and the above-described embodiments should be regarded as illustrative rather than restrictive. Accordingly, it should be appreciated that variations to those embodiments may be made by those skilled in the art without departing from the scope of the systems, apparatuses, and methods as defined by the following claims.

What is claimed is:

1. A method for the heteroepitaxial deposition of diamond on a substrate by means of chemical vapor deposition (CVD), comprising the following steps:
a. Providing a substrate having at least one first side and depositing a nucleation layer on at least a part of the first side of the substrate;
b. Depositing a first diamond layer on the nucleation layer by chemical vapor deposition;
c. Partial removal of the first diamond layer by dry chemical etching, wherein the dry chemical etching is carried out by the action of a plasma which comprises at least hydrogen and oxygen;
d. Depositing a second diamond layer by chemical vapor deposition on the etched surface of the first diamond layer; and
e. Cyclic repetition of the method steps c) and d).

2. The method of claim 1, wherein the method steps c) and d) are repeated from about 10 times to about 80 times.

3. The method of claim 1, wherein the method steps c) and d) are repeated until the diamond has an overall thickness of more than 200 μm.

4. The method of claim 1, wherein the substrate comprises any of silicon, yttrium, zirconium oxide, aluminum nitride, and strontium titanate.

5. The method of claim 4, wherein the substrate comprises a coating, said coating comprising iridium.

6. The method of claim 1, wherein at least one specific first or second diamond layer has a layer thickness ranging from about 0.5 μm to about 1 μm.

7. The method of claim 1, wherein at least one specific first or second diamond layer has a layer thickness ranging from about 4 μm to about 30 μm.

8. The method of claim 1, wherein the first four to eight diamond layers are deposited with a smaller layer thickness than the subsequent diamond layers.

9. The method of claim 1, wherein at least one specific first or second diamond layer is deposited with a orientation.

10. The method of claim 1, wherein the partial removal of the diamond layers by dry chemical etching causes the formation of pyramids on a surface of said etched diamond layer, said pyramids having any of at least one side surface with a orientation and a height of about 2 μm to about 5 μm.

11. The method of claim 1, wherein a last diamond layer is deposited undoped and the preceding diamond layers comprise a dopant.

12. The method of claim 1, wherein the deposition of diamond in the method steps b) and d) is carried out by the action of a plasma which comprises at least hydrogen and a hydrocarbon.

13. The method of claim 1, comprising further removing the substrate after the deposition of diamond.

14. A method for the heteroepitaxial deposition of diamond on a substrate by means of chemical vapor deposition (CVD), comprising the following steps:
a. Providing a substrate having a diameter of more than 5 cm and less than 26 cm and having at least one first side and depositing a nucleation layer on at least a part of the first side of the substrate;
b. Depositing a first diamond layer on the nucleation layer by chemical vapor deposition by the action of a plasma which comprises at least hydrogen and a hydrocarbon;
c. Partial removal of the first diamond layer by dry chemical etching, wherein the dry chemical etching is carried out by the action of a plasma which comprises at least hydrogen and oxygen;
d. Depositing a second diamond layer by chemical vapor deposition on the etched surface of the first diamond layer by the action of a plasma which comprises at least hydrogen and a hydrocarbon; and
e. Cyclic repetition of the method steps c) and d) until the diamond has an overall thickness of more than 200 μm.

15. The method of claim 14, wherein the substrate comprises any of silicon, yttrium, zirconium oxide, aluminum nitride, and strontium titanate.

16. The method of claim 14, wherein the first four to eight diamond layers are deposited with a smaller layer thickness than the subsequent diamond layers.

17. The method of claim 14, wherein the partial removal of the diamond layers by dry chemical etching causes the formation of pyramids on a surface of said etched diamond layer, said pyramids having any of at least one side surface with a orientation and a height of about 2 μm to about 5 μm.

18. A method for the heteroepitaxial deposition of diamond on a substrate by means of chemical vapor deposition (CVD), comprising the following steps:
a. Providing a substrate having at least one first side and depositing a nucleation layer on at least a part of the first side of the substrate;
b. Depositing a first diamond layer on the nucleation layer by chemical vapor deposition by the action of a plasma which comprises at least hydrogen and a hydrocarbon;
c. Partial removal of the first diamond layer by dry chemical etching, wherein the dry chemical etching is carried out by the action of a plasma which comprises at least hydrogen and oxygen;
d. Depositing a second diamond layer by chemical vapor deposition on the etched surface of the first diamond layer by the action of a plasma which comprises at least hydrogen and a hydrocarbon; and
e. Cyclic repetition of the method steps c) and d) until the diamond has an overall thickness of more than 200 μm, wherein
the first four to eight diamond layers are deposited with a smaller layer thickness than the subsequent diamond layers.

19. The method of claim 18, wherein the substrate comprises any of silicon, yttrium, zirconium oxide, aluminum nitride, and strontium titanate.

20. The method of claim 18, wherein at least one specific first or second diamond layer has a layer thickness ranging from about 0.5 μm to about 1 μm or ranging from about 4 μm to about 30 μm.
